(19) United States
(12) Patent Application Publication
(10) Pub. No.: US 2025/0022711 A1
(43) Pub. Date: Jan. 16, 2025

(54) METHOD FOR PRODUCING A STRESS STATE IN A SEMICONDUCTIVE LAYER

(71) Applicant: COMMISSARIAT A L'ENERGIE ATOMIQUE ET AUX ENERGIES ALTERNATIVES, Paris (FR)

(72) Inventors: Emmanuel AUGENDRE, Grenoble Cedex 09 (FR); Pablo ACOSTA ALBA, Grenoble Cedex 09 (FR); Shay REBOH, Grenoble Cedex 09 (FR); Olivier ROZEAU, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/768,121

(22) Filed: Jul. 10, 2024

(30) Foreign Application Priority Data
Jul. 12, 2023 (FR) 2307488

(51) Int. Cl. H01L 21/225

(52) U.S. Cl. CPC H01L 21/2251

(57) ABSTRACT

A method for producing a uniaxial stress state in a semiconductive layer, may include: providing a stack including a support, the semiconductive layer, and an inserted fuse layer; forming a stress donor layer on the semiconductive layer; partially altering the stress donor layer, modifying a first stress state of the layer to obtain a second stress state in one single direction; and melting the fuse layer, such that the stress donor layer transfers, by relaxation, the second stress state into the semiconductive layer.

### TECHNICAL FIELD

The present invention relates to the field of microelectronics and, more specifically, to that of methods making it possible to mechanically strain or stress a semiconductive layer. A particular application relates to producing Complementary Metal-Oxide Semiconductor (CMOS) transistors on a Fully Depleted Silicon On Insulator (FDSOI)-type substrate.

### PRIOR ART

In this field, it is desirable to increase the mobility of the charge carriers to reach the best compromise between performance and energy consumption.

The mobility of the electrons can typically be increased (respectively decreased) by a mechanical stress in tension (respectively in compression) of the semiconductive material wherein they transit, while the mobility of the holes can conversely be increased (respectively decreased) when the semiconductor is in compression (respectively in tension).

Thus, to improve the performance of the transistors, it can be provided to make their channel region of a semiconductive material having a mechanical stress in tension or in compression. Typically, for transistors of which the channel is made of silicon and of N-type (the main carriers are electrons), the most favourable configurations are a channel in biaxial traction or in uniaxial traction in the direction of the electronic transport if the uniaxial stress is greater than or equal to 1.4 GPa. For transistors of which the channel is made of silicon-germanium and of P-type (the main carriers are holes), the most favourable configuration is a uniaxial channel in compression in the direction of the electronic transport.

Document FR3120738 A1 discloses an indirect method making it possible to modify a stress state of a semiconductive layer. This method is based on the use of a fuse layer inserted between the semiconductive layer to be strained and the support. A stress donor layer is moreover deposited on the semiconductive layer to be strained. A heat treatment is then performed to melt the fuse layer. The stress donor layer thus imposes a biaxial straining on the semiconductive layer. This biaxial straining of the semiconductive layer remains after solidification of the fuse layer and removal of the stress donor layer. To obtain a uniaxial stress, the semiconductive layer is then typically cut into strips such that the stress relaxes along the width of the strips. Only the stress along the length of the strips subsists.

This cutting into strips consumes material. This loss of material is conveyed by a reduced integration density.

An aim of the present invention is to overcome the limitations of this known method.

In particular, an aim of the present invention is to propose a method for producing a uniaxial stress state in a semiconductive layer, enabling a greater integration density.

### SUMMARY

To achieve this aim, according to an embodiment, a method for producing a uniaxial stress state in a semiconductive layer is provided, said method comprising at least:
A provision of a stack comprising a support, the semiconductive layer and a so-called fuse layer inserted between the support and the semiconductive layer,
A formation of a stress donor layer on the semiconductive layer,
A definition of patterns after formation of the stress donor layer,
A formation, from said patterns, of regions surrounded by trenches extending up to into the semiconductive layer,
A partial alteration of the stress donor layer at said regions, configured to modify a first stress state of said stress donor layer so as to obtain a second stress state mainly in a determined direction,
An at least partial melting, such that the stress donor layer transfers at least partially, by relaxation, the second stress state in the semiconductive layer, such that the semiconductive layer has a uniaxial stress state in said determined direction.

Thus, contrary to the known method mentioned above, the transformation of an initial stress state, in this case, the first stress state, which is typically a biaxial stress state, into a uniaxial stress state, in this case, the second stress state, is done prior to the melting of the fuse layer, upstream of the transfer of the stress state into the semiconductive layer. The stress state transferred from the stress donor layer, during melting, is thus directly a uniaxial stress state. It is not necessary to implement other types of modification of the stress state in the semiconductive layer after this transfer. In particular, the steps of cutting the expensive semiconductive layer made of consumed material are removed.

The transfer of a uniaxial stress state according to the invention makes it possible to further increase the semiconductive layer thickness with no crystalline defects. In the known method, the transferred stress state is a biaxial stress state. For a given stress intensity, the critical thickness of the material (from which a plastic relaxation of the stress is observed, generating crystalline defects) is greater when the stress is uniaxial than when it is biaxial. Directly transferring a uniaxial stress state into the semiconductive layer thus makes it possible to produce a semiconductive layer without crystalline defects which are thicker than that achievable by the known method.

Moreover, the modification of the stress state upstream of the transfer offers more options in terms of engineering the stress state. The modification can be typically configured to produce a uniaxial stress state in compression or a uniaxial stress state in tension, which is no longer possible after transfer by simple cutting of the semiconductive layer, as in the prior art.

The modification of the first stress state and a second uniaxial stress state is done by partial alteration of the stress donor layer. This alteration can be advantageously performed by usual microelectronic steps, such as a localised implantation or an etching of trenches in the stress donor layer.

Consequently, and advantageously, the method for producing a uniaxial stress state in a semiconductive layer according to the present invention enables, in particular, a saving of material and a better versatility with respect to the known method described above. By implementing the method according to the present invention, the integration density can be advantageously increased.

Another aspect of the invention relates to a method for manufacturing a transistor comprising the implementation of the method for producing a uniaxial stress state according to the invention. According to this manufacturing method, the transistor comprises a channel region made in the semiconductive layer having the uniaxial stress state.

Other aims, features and advantages of the present invention will appear upon examining the description below and the accompanying drawings. It is understood that other advantages can be incorporated.

### BRIEF DESCRIPTION OF THE FIGURES

In particular, the aims, objectives, as well as the features and advantages of the invention will best emerge from the detailed description of at least one embodiment of the latter, which is illustrated by the following accompanying drawings, wherein:

FIG. 1 illustrates, as a cross-section, a stack according to an embodiment of the present invention.

FIG. 2 illustrates, as a top view, the stack illustrated in FIG. 1, according to an embodiment of the present invention.

FIG. 3 illustrates, as a cross-section, a method step (formation of isolating trenches and of regions) according to an embodiment of the present invention.

FIG. 4 illustrates, as a top view, the method step (formation of isolating trenches and of regions) illustrated in FIG. 3, according to an embodiment of the present invention.

FIG. 5 illustrates, as a cross-section, a method step (formation of strips implanted in the stress donor layer) according to an embodiment of the present invention.

FIG. 6, illustrates, as a top view, the method step (formation of strips implanted in the stress donor layer) illustrated in FIG. 5, according to an embodiment of the present invention.

FIG. 7 illustrates, as a cross-section, a method step (partial melting of the fuse layer) according to an embodiment of the present invention.

FIG. 8 illustrates, as a top view, the method step (partial melting of the fuse layer) illustrated in FIG. 7, according to an embodiment of the present invention.

FIG. 9 illustrates, as a cross-section, a method step (removal of the stress donor layer) according to an embodiment of the present invention.

FIG. 10 illustrates, as a top view, the method step (removal of the stress donor layer) illustrated in FIG. 9, according to an embodiment of the present invention.

FIG. 11 illustrates, as a cross-section, a method step (formation of relaxation trenches in the stress donor layer) according to another embodiment of the present invention.

FIG. 12 illustrates, as a top view, the method step (formation of relaxation trenches in the stress donor layer) illustrated in FIG. 11, according to another embodiment of the present invention.

FIG. 13 illustrates, as a cross-section, a method step (filling of the isolating trenches) according to another embodiment of the present invention.

FIG. 14 illustrates, as a top view, the method step (filling of the isolating trenches) illustrated in FIG. 13, according to another embodiment of the present invention.

FIG. 15 illustrates, as a cross-section, a method step (removal of the stress donor layer) according to another embodiment of the present invention.

FIG. 16 illustrates, as a top view, the method step (removal of the stress donor layer) illustrated in FIG. 15, according to another embodiment of the present invention.

FIG. 17 illustrates the dependency of the straining obtained in a 10 nm silicon film on 20 nm buried oxide according to Young's modulus and to the stress of a stress donor layer, 100 nm thick, according to an embodiment of the present invention.

The drawings are given as examples and are not limiting of the invention. They constitute principle schematic representations intended to facilitate the understanding of the invention and are not necessarily to the scale of practical applications. In particular, the thicknesses of the different layers and the dimensions of the different patterns which are illustrated by diagrams which are not representative of reality.

### DETAILED DESCRIPTION

Before starting a detailed review of embodiments of the invention, optional features are stated below, which can optionally be used in association or alternatively:

According to an example, the method further comprises a filling of the trenches to form isolating trenches, after melting of the fuse layer and before a removal of the stress donor layer. This makes it possible to confine certain regions of the semiconductive layer between the isolating trenches to avoid a relaxation, typically in the direction y of uniaxial stress, semiconductive layer regions after removal of the stress donor layer. This makes it possible, for example, to increase the uniaxial stress state. This makes it possible, for example, to limit stress losses during the transfer of the stress state into the semiconductive layer.

According to an example, the partial alteration comprises an ion implantation in a part of the stress donor layer forming implanted strips oriented in the determined direction, said implanted strips extending over the entire dimension of the stress donor layer in the determined direction. This implantation is done typically along the entire thickness of the stress donor layer. The width of the implanted strips is preferably less than or equal to half the thickness of the stress donor layer. Typically, if the implanted strips aim to relax the stress donor layer in a direction x, the width along x of the implanted strips is preferably chosen as low as possible (this minimum width is typically fixed by the resolution of the lithography equipment used to produce the mask defining the strips to be implanted). If the implanted strips aim to induce a uniaxial compression state along y in the stress donor layer, the width along x of the implanted strips can be chosen from around half the thickness of the stress donor layer, even around one third of the thickness of the stress donor layer. The length along y of the implanted strips is typically widely greater, i.e. at least ten times greater, than the thickness of the stress donor layer. This limits or avoids a relaxation of the stress donor layer along y.

According to an example, the regions have a dimension in the determined direction, significantly greater than the thickness of the stress donor layer, typically at least six times greater than the thickness of the stress donor layer. This makes it possible to optimise the uniaxial stress transfer in the determined direction in the semiconductive layer.

According to an example, the implanted ions are argon-based. The stress state of the stress donor layer is thus modified without exposing the underlying semiconductive layer. The semiconductive layer therefore remains protected with respect to other method steps, typically during formation, filling and planarising of the isolating trenches.

According to an example, the first stress state is substantially zero and the second stress state corresponds to a uniaxial compression. The stress donor layer can be initially relaxed, before alteration. An argon implantation in strips oriented in the determined direction makes it possible, typically to generate such a uniaxial compression in a SiN-based stress donor layer, for example.

According to an example, the first stress state corresponds to a biaxial tension and the second stress state corresponds to a uniaxial tension. The stress donor layer, for example SiN-based, can be initially in biaxial tension, before alteration. An argon implantation in strips oriented in the determined direction makes it possible, typically to relax the stress in these strips. The stress donor layer thus has relaxed strips and a residual stress state in uniaxial tension between the relaxed strips.

According to an example, the partial alteration comprises a formation of relaxation trenches in the stress donor layer, oriented in the determined direction. It is thus possible to pass from a biaxial stress state to a uniaxial stress state, by forming relaxation trenches in the stress donor layer, preferably along the entire thickness of the stress donor layer.

According to an example, the relaxation trenches are separated by stress donor layer strips having a width around equal to half the thickness of the stress donor layer.

According to an example, the partial alteration comprises a formation of relaxation trenches in the stress donor layer of certain regions, and an ion implantation in strips of the stress donor layer for other regions. The two types of partial alteration can thus coexist for different regions of one same plate or wafer.

According to an example, the stack comprises an isolating layer between the semiconductive layer and the fuse layer. According to an example, the isolating layer is silica-based. It preferably has a thickness of between 10 nm and 25 nm. This architecture typically corresponds to FDSOI technology. The low stiffness of silica, which has a Young's modulus E of around 50 GPa, and the limited thickness favouring the transmission of a stress state between the stress donor layer and the semiconductive layer.

According to an example, the stress donor layer is silicon nitride-based. This material has the advantage of being transparent in UV, in a wavelength range suiting the melting of the fuse layer. It can also be advantageously used for filling isolating trenches, typically shallow trench isolation (STI) isolating trenches implemented for the lateral isolation in FDSOI technology. The steps of filling the isolating trenches and of depositing the stress donor layer can thus be done simultaneously, at least partially. This decreases the number of steps and the cost of the method.

According to a preferred option, the melting is done by thermal annealing of the rapid thermal annealing type, typically over the entire extent of the fuse layer, i.e. over the entire plate. Using a rapid thermal annealing enables a collective heating of the regions formed in the semiconductive layer, independently of the dimensions of said regions. According to another example, this thermal annealing is performed using a nanosecond laser, typically by scanning the plate with the laser beam. Using a laser enables a rapid and localised thermal rise of the layer stack at a predetermined temperature enabling the melting of the fuse layer while avoiding an unintentional diffusion of atoms in the stack. The thermal budget thus remains limited. According to an example, the laser is a pulsed laser having pulses, the duration of which is less than one microsecond and preferably between 10 ns and 1000 ns, advantageously between 20 ns and 500 ns. The laser has a wavelength typically of between 100 nm and 550 nm, and preferably of between 250 nm and 400 nm.

According to an example, the fuse layer is amorphous. This makes it possible to lower the melting point of the fuse layer, compared with a fuse layer with the basis of the same material in crystalline form. For example, an SiGe-based fuse layer in crystalline form containing 65% of Ge melts at around 1100° C., while an SiGe-based fuse layer in amorphous form containing 65% of Ge melts at below 1000° C.

According to an example, the amorphous fuse layer is formed by epitaxy before being amorphised by implantation. This makes it possible to obtain a slightly rough amorphous fuse layer and containing little hydrogen.

According to an example, the semiconductive layer is silicon- or silicon-germanium-based, and the fuse layer is silicon-germanium- or germanium-based and has a content of germanium greater than the semiconductive layer. The greater the germanium content is, the more the melting point decreases. Advantageously, the fuse layer melts, while the semiconductive layer remains in the solid state. The relative compositions of the fuse and semiconductive layers are typically chosen for this purpose. According to an example, the semiconductive layer is silicon-germanium- or germanium-based and the fuse layer is silicon-germanium and tin- or germanium and tin-based. Tin also lowers the melting point of germanium-based alloys.

Unless incompatible, technical features described in detail for a given embodiment can be combined with the technical features described in the context of other embodiments described as an example and in a non-limiting manner. In particular, elements described or illustrated for certain embodiments of the method can be combined, so as to form another embodiment, which is not necessarily illustrated or described. Such an embodiment is clearly not excluded from the invention.

It is specified that, in the scope of the present invention, the terms “on”, “surmounts”, “covers”, “underlying”, “opposite” and their equivalents do not necessarily mean “in contact with”. Thus, for example, the deposition of a first layer on a second layer, does not compulsorily mean that the two layers are directly in contact with one another, but means that the first layer at least partially covers the second layer, by being either directly in contact with it, or by being separated from it by at least one other layer or at least one other element.

A layer can moreover be composed of several sublayers made of one same material or made of different materials.

By a substrate, a stack, a layer “with the basis” of a material A, this means a substrate, a stack, a layer comprising this material A only, or this material A and optionally other materials, for example, alloy elements and/or doping elements. Thus, a silicon-based layer means, for example, an Si, n-doped Si, p-doped Si layer.

The present invention enables, in particular, the production of a uniaxial stress state in a semiconductive layer. This semiconductive layer corresponds typically to a upper layer, called “topSi”, of a silicon on insulator (SOI) substrate. The invention can be implemented to produce different microelectronic devices or components according to architectures of the FDSOI, FinFET (field effect transistor, the channel of which is formed in a fin shape) or also “nanosheet” (stack of thin layers forming active layers of transistors) type. The invention can also be implemented to produce different optoelectronic devices or components, for example lasers, birefringent waveguides or amplifiers. The invention can be implemented for broadly for producing any device comprising a thin semiconductive layer having a uniaxial stress state.

Several embodiments of the invention implementing successive steps of the production method are described below. Unless explicitly mentioned, the adjective “successive” does not necessarily imply, even if this is generally preferred, that the steps follow one another immediately, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time, and in the sequence of phases of the method.

A preferably orthonormal system, comprising the axes x, y, z is represented in the accompanying figures. When one single system is represented on one same set of figures, this system applies to all the figures of this set.

In the present patent application, the thickness of a layer is taken in a direction normal to the main extension plane of the layer. The height of a device or the depth of a pattern, for example, a trench, are taken in the direction z. Thus, a layer typically has a thickness along z and a trench typically has a depth along z. The relative terms “on”, “surmounts”, “under”, “underlying” refer to positions taken in the direction z.

The terms “vertical”, “vertically” refer to a direction along z. The terms “horizontal”, “horizontally” refer to a direction in the plane xy. The term “lateral” refers to a plane xz or yz. Thus, the lateral flanks of the isolating trenches extend parallel to a plane yz and/or xz. Unless explicitly mentioned, the thickness, the height and the depth are measured along z.

An element located “in vertical alignment with” or “to the right of” another element means that these two elements are both located on one same line perpendicular to a plane wherein a lower or upper face of a substrate mainly extends, i.e. on one same line oriented vertically in the figures.

The method comprises a definition of patterns after formation of the stress donor layer, and a formation of regions in the semiconductive layer from said patterns. These patterns and regions are not assimilable to a partial alteration of the stress donor layer. These patterns and regions aim to structure the stack, in particular in view of an integration within operational devices such as transistors. The dimensions of these patterns, in particular along y and/or along x, are a lot greater than the dimensions of the implanted strips or relaxation trenches, in particular a lot greater than their thickness or their height.

A mechanical stress state is generally described by a tensor. In the scope of the present invention, only the diagonal components of the tensor, and in particular the components in the plane xy, are considered.

By mechanical straining of a semiconductive layer, this means that its material has its crystalline mesh parameter(s) extended or shortened.

In the case where the strained mesh parameter is greater than the so-called “natural” parameter of a crystalline material, this is called in straining or in tension. When the strained mesh parameter is smaller than the natural mesh parameter, the material is called in compressive straining or in compression.

In these mechanical straining states, mechanical stress states are associated. However, it is also common to refer to these strain states as mechanical stress states. Below in this application, this notion of strain will generically mean “stress”.

The stress donor layer is also called “stressor”.

By melting, this means the passage, transitionally, of at least one given thickness of the fuse layer from a solid state to a liquid state. Advantageously, the material of the fuse layer has a melting point or liquidus temperature less than the melting point or liquidus temperature of the semiconductive material of the semiconductive layer.

Below, the term “absorption” or its equivalents refers to the phenomenon by which the energy of an electromagnetic wave is transformed into another energy form, for example, in the form of heat. In the present description, a material is considered as absorbent, as soon as it absorbs at least 50% of a light radiation, preferably at least 75% and advantageously at least 90%. It can be characterised by an absorption factor of between 0 and 1.

Moreover, a layer is called transparent when it has a transmission coefficient greater than or equal to 50%, preferably 75%, even 90% for a central wavelength of the spectral range of the incident electromagnetic radiation.

To determine the composition and the stress state of the different layers, electron microscopy analyses, in particular scanning electron microscopy (SEM) or transmission electron microscopy (TEM) analyses can be proceeded with.

The chemical compositions of the different layers or regions can be determined using the well-known EDX or X-EDS (energy dispersive x-ray spectroscopy) method.

This method is well-suited for analysing the composition of thin layers, such as the semiconductive layer and the stress donor layer. It can be implemented on metallurgic cuts within an SEM or a TEM.

Precession electron diffraction (PED) can be implemented within a TEM to determine the stress state of thin layers, such as the semiconductive layer. Other electron microscopy or diffraction techniques can also be considered. Optical spectroscopy techniques, for example, Raman spectroscopy, can also be implemented.

These techniques make it possible, in particular, to determine the stress state of the semiconductive layer, and the arrangement and the composition of the different layers within the stack.

A semiconductive layer in uniaxial tension above a silicon-germanium-based “solidified” layer (corresponding to a fuse layer), can be implementation indices of the method according to the present invention.

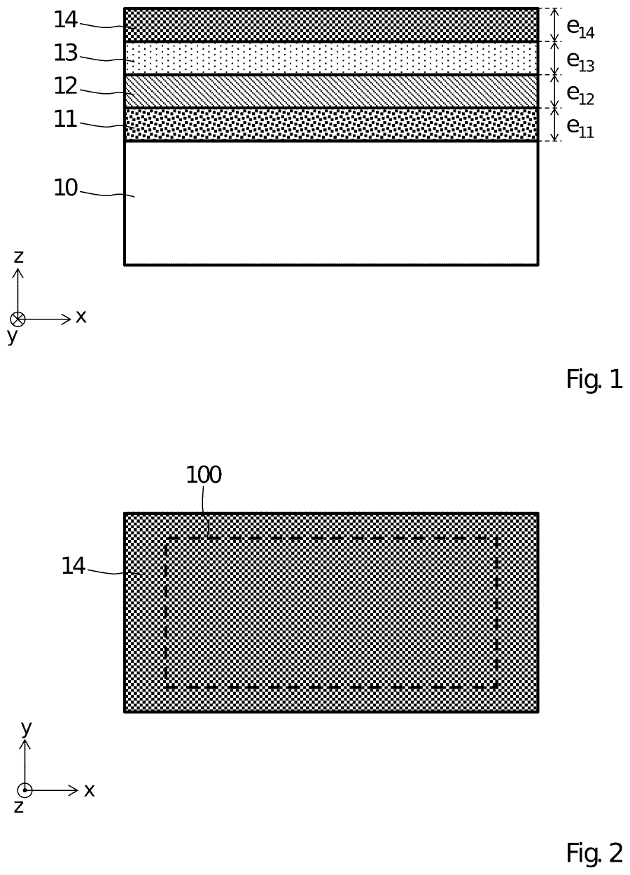

FIG. 1 illustrates a stack comprising a support 10, a fuse layer 11, an isolating layer 12, a semiconductive layer 13 and a stress donor layer or stressor 14.

The support 10 typically corresponds to a so-called “bulk” solid substrate, made of monocrystalline silicon. The support 10 typically has a resistivity of around 20 Ω·cm. For certain applications, for example, for RF applications, the support 10 can have a resistivity which is greater than or equal to 100 Ω·cm. The stack can comprise other layers, typically between the substrate 10 and the fuse layer 11. A porous silicon layer or a layer comprising a zone capable of trapping a large quantity of mobile charges (generally called “trap rich”), can for example be inserted between the substrate 10 and the fuse layer 11. The fuse layer 11 is preferably with the basis of a monocrystalline or polycrystalline SiGe alloy, the Ge content of which is chosen, such that the liquidus of the alloy is notably lower than the rest of the stack, and in particular, lower than the liquidus or the melting point of the semiconductive layer 13. A difference in melting point/liquidus temperature between the semiconductive layer 13 and the fuse layer 11 greater than or equal to 50° C., and preferably greater than or equal to 80° C., is typically required. Thus, the choice of the composition of the fuse layer 11 is made relative to the composition of the semiconductive layer 13.

For example, when the semiconductive layer 13 is made of silicon, the fuse layer 11 can have a germanium content of between 30 at. % and 99 at. %, advantageously between 40 at. % and 70 at. %.

If the semiconductive layer 13 contains germanium, the fuse layer 11 can contain tin. This contributes to maintaining an acceptable difference in melting point/liquidus temperature between the semiconductive layer 13 and the fuse layer 11.

The fuse layer 11 can be formed by epitaxy or by chemical vapour deposition (CVD) on the support 10. The fuse layer 11 typically has a thickness e₁₁ of between 5 nm and 20 nm. When the semiconductive layer 13 is formed directly in contact with the fuse layer 11, by epitaxy, the fuse layer 11 is preferably monocrystalline. The thickness of the fuse layer 11 is preferably less than its critical thickness for plastic relaxation (see, for example, in the case of an SiGe-based fuse layer 11 on an Si-based support 10, the document “Critical thickness for plastic relaxation of SiGe on Si(001) revisited” by J. M. Hartmann et al. published in Journal of Applied Physics 110, 083529 (2011)). The formation of dislocations in the semiconductive layer 13 during the growth of the semiconductive layer 13 on the fuse layer 11 is thus avoided.

According to an option, the fuse layer 11 is amorphous. This makes it possible to lower the melting point of the fuse layer 11, compared with a crystalline fuse layer 11 of the same chemical composition. As an example, an SiGe-based fuse layer in crystalline form having a Ge concentration of 65 at. % melts at around 1100° C., while an SiGe-based fuse layer in amorphous form having the same Ge concentration of 65 at. % melts at below 1000° C.

The amorphous fuse layer 11 can be formed in two steps. A first step consists of epitaxially growing the fuse layer 11 in crystalline form on the support 10. A second step consists of amorphising the fuse layer 11 by ion implantation. This makes it possible to obtain a slightly rough amorphous fuse layer and containing little hydrogen.

The implantation conditions for the amorphisation of at least one part of the thickness of the fuse layer 11 can be defined using a simulation tool, for example, using software of the C-TRIM type (CTRIM for “Crystal Transport of Ions in Matter”) using algorithms based on the Monte Carlo method. For the specific case of an Si semiconductive layer 13 and of an SiGe fuse layer 11, Si ions can be used, for example. The implanted dose is calculated so as to cause the amorphisation of the SiGe fuse layer. A typical dose range for SiGe can be between 1.5e14 and 3e14 at/cm². The amorphisation depth preferably extends along the entire thickness e₁₁ of the fuse layer 11.

The isolating layer 12 is optional. It can be of the “buried oxide” or “BOX” type in an SOI (“Silicon On Insulator”) architecture. It is preferably silica-based, and has a thickness e₁₂ typically of between 10 nm and 25 nm. The low stiffness of silica, which has a Young's modulus E of around 50 GPa, and the limited thickness favour the transmission of a stress state between the stress donor layer 14 and the semiconductive layer 13. This configuration is favourable in the case of an FDSOI architecture. For certain applications, for example in the case of a high vertical capacitance structure, the isolating layer 12 can be alternatively with the basis of a high permittivity material. In this case, the isolating layer 12 can be alumina Al₂O₃-based, or a hafnium silicon oxynitride HfSiON with thicknesses e₁₂ of between 5 nm and 25 nm.

The semiconductive layer 13 is typically intended to form one or more active zones of a microelectronic device. The semiconductive layer 13 is with the basis of a doped or intrinsic semiconductive material. It can have a P-type or N-type doping, according to the applications.

According to an example, the semiconductive layer 13 is made of monocrystalline silicon and has a thickness e₁₃ of between 5 nm and 20 nm. To produce the corresponding SOI substrate, a low-temperature manufacturing sequence can be advantageously used, for example, such as disclosed in document FR3116940 A1 or in document FR3125631 A1, integrated, in this case, by reference. Such a low-temperature manufacturing sequence makes it possible to remain below the liquidus temperature of the fuse layer 11 during the formation of the semiconductive layer 13. Such a low-temperature manufacturing sequence can be, in particular, implemented when the fuse layer 11 contains more than 60% of Ge, or when it is desirable that this remains amorphous before melting and transfer of the stress state in the semiconductive layer 13.

According to another example, the semiconductive layer 13 is with the basis of an SiGe alloy with a Ge atomic fraction of between 10% and 60%. In this case, the semiconductive layer 13 preferably has a thickness less than the critical thickness, typically of between 5 nm and 20 nm. When such a semiconductive layer 13 is used, the fuse layer 11 typically has a greater Ge content and optionally contains Sn.

According to another example, the semiconductive layer 13 comprises a plurality of alternate silicon and silicon-germanium monocrystalline layers. The silicon-germanium layers can typically comprise between 20 and 60% of Ge. Each of the monocrystalline layers typically has a thickness of between 5 nm and 10 nm. Such a semiconductive layer 13 enables, in particular, the formation of “nanosheet”-type transistors.

The stress donor layer or stressor 14 is preferably silicon nitride SiN-based. This material has the advantage of being transparent in UV, in a range of wavelengths suiting the melting of the fuse layer 11. This material is also widely used for other types of method in the field of microelectronics. It is well-known and fully compatible with numerous applications. Moreover, the melting point of silicon nitride is around 1900° C., that is strictly greater than that of silicon and of most semiconductors used as a semiconductive layer 13 and/or a fuse layer 11. The stressor 14 thus remains in the solid state during the stress transfer step involving the melting of the fuse layer 11. The stressor 14 typically has a thickness e₁₄ of between 30 nm and 200 nm.

The stressor 14 can be deposited by CVD on the semiconductive layer 13. This deposition can be plasma-enhanced. According to an option, a thin oxide, of around 1 nm to 5 nm, is formed on the semiconductive layer 13 before the deposition of the silicon nitride-based stressor 14 (not illustrated). This makes it possible to facilitate the subsequent removal of the stressor 14.

According to an option, the SiN-based stressor 14 is deposited without internal stress. Alternatively, different stress states can be obtained during the deposition of SiN. According to an option, an SiN-based stressor 14 in tensile stress, typically up to 1.5 GPa, can be formed by CVD deposition. According to another option, an SiN-based stressor 14 in compressive stress, typically up to −2 GPa even −3 GPa, can be formed by CVD deposition. Other precisions on the type of stress according to the type of deposition or to the deposition conditions can be found in the document, “A comparison of the mechanical stability of silicon nitride films deposited with various techniques” by Pierre Morin et al. published in Applied Surface Science 260 (2012) 69-72, in the case of a silicon nitride-based stressor 14.

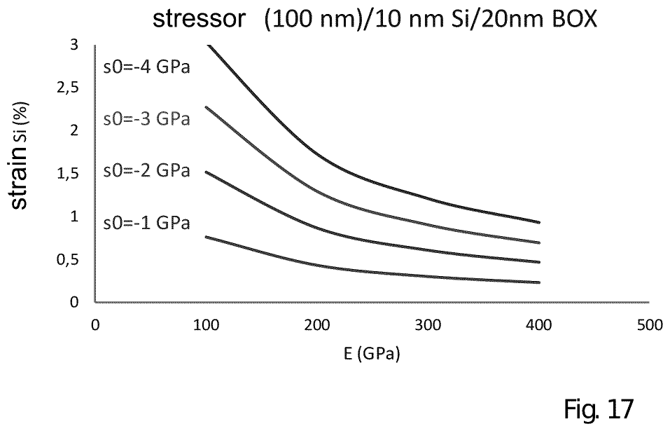

Other materials can be used for the stressor 14, for example Al₂O₃ or Ga₂O₃. The parameters to be considered for the choice of the material of the stressor 14 are mainly the transparency in UV (when the melting is done by laser), the capacity of being deposited with a high internal stress and a relatively low Young's modulus. FIG. 17 illustrates the dependency of the strain obtained in an Si layer, 10 nm thick on a buried oxide layer, 20 nm thick, according to the Young's modulus E and to the initial stress s0 of a stressor, 100 nm thick. A silicon nitride-based stressor deposited by plasma-enhanced CVD (PECVD) typically having an initial compressive stress of −2 GPa makes it possible to obtain a strain of the Si layer between 1 and 1.5%.

As illustrated in FIG. 2, a region of the semiconductive layer to be strained can be defined beforehand by way of a pattern 100. This can be a sequence which is common to the FDSOI manufacturing method aiming to form active transistor zones. The pattern 100 typically comprises a masking protecting the stack in the region to be preserved.

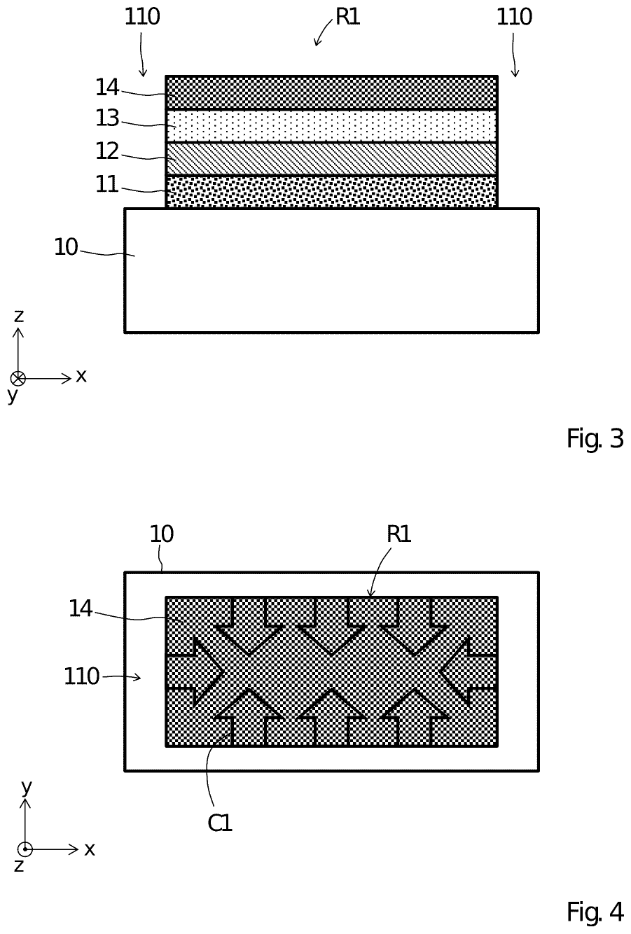

As illustrated in FIGS. 3, 4, a structuring of the stack can be done by etching exposed zones, around the pattern 100. This etching can be done by RIE (“Reactive Ion Etching”) dry etching. The etching is done, typically along the entire thickness of the stack, at least up to the base of the fuse layer 11, typically over a depth of around 200 nm from the upper face of the semiconductive layer 13. Trenches 110 surrounding a region R1 of the semiconductive layer 13 are thus formed. One or more steps of defining patterns and etching can be concatenated, for example in the scope of a structuring called “double patterning”, according to the dimensions targeted for the region R1 and to the lithography equipment used. Different depths of trenches 110 can also be achieved, for example in the scope of a so-called “double STI” technology.

It is advantageous to define the regions R1 of the largest dimension possible in the direction y to optimise the uniaxial stress transfer along y in the semiconductive layer 13. An option consists of providing consecutive active zones of the same type of conductivity (N or P) abutted in the direction y (circulation direction of the current) by replacing the separation trenches 110 by inactive gates. Such an organisation is called “in continuous active zone” or “continuous RX”. According to an option, the dimension along y of the region R1 is greater than or equal to six times the stressor thickness. This makes it possible to reach the maximum stress value theoretically transferable by the stressor, by moving away from the free edge of the region R1. The continuous active zone topology ultimately makes it possible to obtain more highly stressed transistor channels, produced from a stressor and of given thickness.

After structuring, the stressor 14 surmounting the semiconductive layer 13 in the region R1 has a biaxial stress state C1 in the plane xy. In FIG. 4, the biaxial stress state C1 illustrated for the stressor 14 is in compression. As stated above, this stress state C1 can be alternatively in tension or zero.

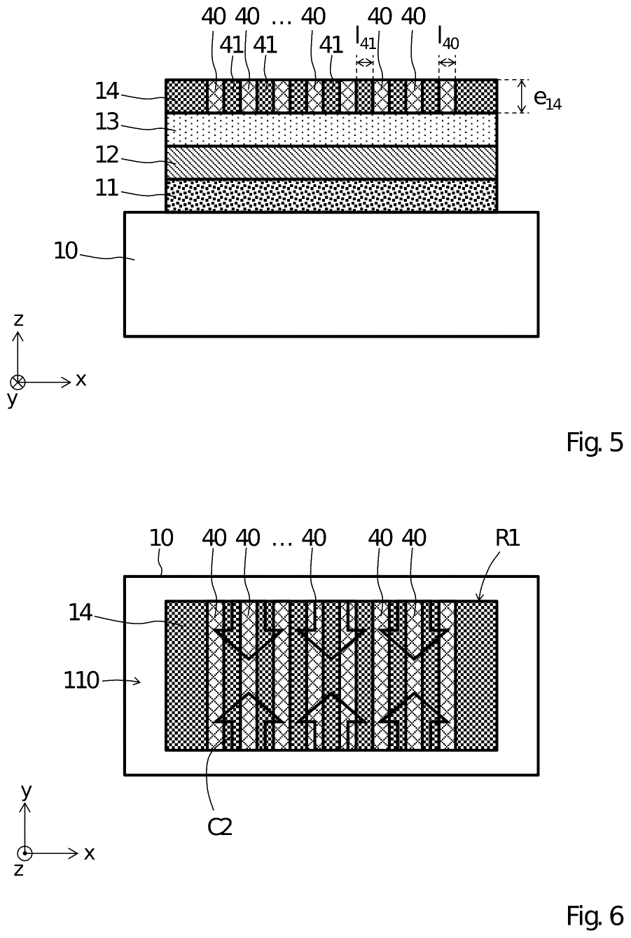

As illustrated in FIGS. 5, 6, according to an embodiment, the stressor 14 is altered by the formation of strips 40 directed along y. This alteration modifies the biaxial stress state C1 to produce a uniaxial stress state C2.

A first way of altering the stressor 14 consists of implanting the strips 40 of the stressor 14 with argon ions. The implantation energy is preferably chosen, such that the argon ions remain confined in the thickness e₁₄ of the stressor 14, while being distributed homogeneously along the thickness e₁₄ of the stressor 14. This implantation typically changes the stress of the stressor 14 strips 40 by offsetting the initial stress in the direction of the compression. The implanted dose, the implantation energy and the thickness e₁₄ of the stressor 14 determine the intensity of the offsetting in stress obtained. For example, the implantation of 3×10e15 at/cm² of argon at 30 keV in a 100 nm silicon nitride layer causes an offsetting in stress of around-4 GPa, in the direction of the compression. By reducing the argon dose to 1×10e14 at/cm² at an energy of 30 keV, the offsetting is around −1.5 GPa, which is sufficient to relax an initially tensile stressor 14 to 1.5 GPa.

The implantation is preferably done after a lithographic masking, configured to define and expose the stressor 14 strips 40, and mask the stressor 14 strips 41.

According to an option, the initial biaxial stress state C1 of the stressor 14 is in tension at 1.5 GPa. The implantation thus forms substantially relaxed nitride strips 40. The stress state C2 of the stressor 14 obtained from the implantation is mainly in uniaxial tension at 1.5 GPa. This is due to the non-implanted stressor 14 strips 41, which have not relaxed in the direction y. The lithography is preferably configured such that the strips 41 have a width I₄₁ along x around equal to half the thickness e₁₄ of the stressor 14. The strips 40 preferably have a width I₄₀ along x as small as enabled by lithography.

According to another option, the initial biaxial stress state C1 of the stressor 14 is relaxed.

The implantation thus forms nitride strips 40 in compression, for example at −1.5 GPa for an implanted dose of 1×10e14 at/cm² at 30 keV. In this case, the stress state C2 of the stressor 14 obtained from the implantation is mainly in uniaxial compression at −1.5 GPa. In this case, the strips 40 preferably have a width I₄₀ along x around equal to half the thickness e₁₄ of the stressor 14, and the strips 41 preferably have a width I₄₁ along x as small as enabled by lithography.

This embodiment of alteration by implantation has the advantage of preserving the region(s) R1 fully covered by the stressor 14. The stress state of the stressor is thus modified without exposing the underlying semiconductive layer 13. The semiconductive layer 13 therefore remains protected with respect to other method steps, typically during the formation, the filling and the planarising of the isolating trenches.

Outside of the regions R1 intended to be uniaxially stressed, the same masking and implantation steps advantageously make it possible to obtain regions totally implanted or totally non-implanted, i.e. totally relaxed or biaxially stressed. Moreover, if the lithography enables the definition of strips in several directions of the plane xy, uniaxial stresses in different directions of the plane xy can be obtained. The method therefore advantageously makes it possible to produce different uniaxial stress states on certain regions, while enabling the joint production of biaxial or relaxed stress states in other regions.

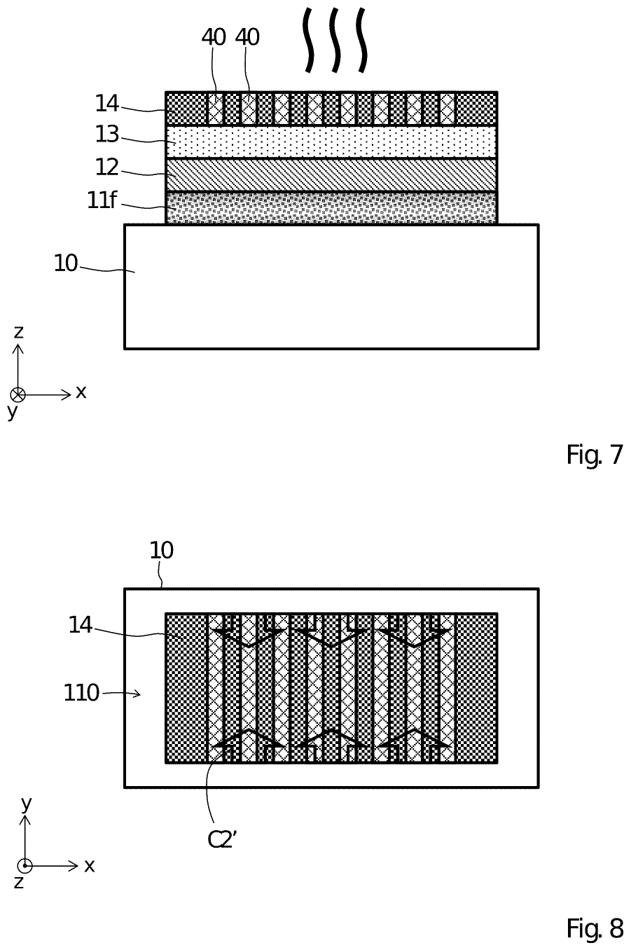

As illustrated in FIGS. 7, 8, after alteration of the stressor 14, a heat treatment is applied to the stack. This heat treatment is configured to melt, at least partially, the fuse layer 11, which becomes a molten layer 11f. This makes it possible to release the stresses imposed on the upper layers 12, 13, 14 by the support 10 and/or the fuse layer 11. All of the layers 12, 13, 14 can thus be relaxed in a configuration of lower elastic energy. In particular, the stressor 14 will at least partially be relaxed by transferring all or some of its stress state C2 to the underlying semiconductive layer 13, and optionally to the isolating layer 12. The stressor 14 has, after relaxation, a residual stress state C2′, less than the stress state C2, even substantially zero. A good transfer of the stress state C2 in the semiconductive layer 13 is favoured by relative low Young's moduli for the stressor 14 and/or the isolating layer 12 with respect to the semiconductive layer 13. The residual stress state C2′ is thus minimised.

In practice, according to a preferred option, the heat treatment can be done by a rapid thermal annealing of the RTA type (“Rapid Thermal Annealing”). This type of RTA annealing advantageously enables a relatively homogeneous heat transfer over the entire extent of the fuse layer, at the wafer, without significant impact of the size of the regions R1. According to another option, the heat treatment is performed using a laser, in particular by subjecting the stack to one or more laser pulse(s). The heat treatment conditions disclosed by document FR3120738 A1 are directly applicable to the method according to the invention. At the end of the laser treatment step, the return into a solid state of the fuse layer 11 makes it possible to freeze the stress in the semiconductive layer 13. The heat treatment step leading to the temporary melting of the fuse layer 11 thus enables a modification of the stress state within the semiconductive layer 13. The use of a laser enables a rapid thermal rise of the layer stack to a predetermined temperature enabling the melting of the fuse layer 11 and the stress modification in the semiconductive layer 13, while limiting the thermal budget used. This makes it possible to avoid an unintentional diffusion of atoms in the stack. The use of the laser also enables a rapid cooling of the stack, once the exposure to the laser has stopped. Another advantage of this type of heat treatment by laser beam is that the modification of the stress state can be done locally, in a spatially targeted manner.

According to an example, the heat treatment step is carried out using a laser by emitting one or more successive laser pulses, the duration of each pulse being less than one microsecond and preferably of between 10 ns and 1000 ns, advantageously between 20 ns and 500 ns. The laser has a wavelength typically of between 100 nm and 550 nm, and preferably of between 250 nm and 400 nm. Long wavelengths can be favoured to avoid or limit the impact of the size of the regions R1, in the plane xy, on the energy absorbed by the stack and in particular, by the fuse layer 11. This makes it possible to ensure homogeneous stress transfer conditions on a large range of region R1 sizes.

The wavelength of the laser, the pulse duration of the laser beam and preferably the energy density of the laser beam are chosen according to the layer stack 11, 12, 13, 14, so as to enable melting, at least locally, of the material of the fuse layer 11 while preserving at least one continuous film of the semiconductive layer 13 in the solid state.

According to a particular example of an embodiment, an energy density of between 0.01 and 2 J/cm² can be provided. A person skilled in the art can rely on a combination of simulation tools, for example, such as stated in the document, “LIAB: a FEniCS-based computational tool for laser annealing simulation”, by Lamagna et al., 2017, to determine the conditions of the rapid laser thermal annealing.

According to an option, from a first stress transfer, the stressor 14 can be replaced or modified again, and a second stress transfer involving a second melting of the fuse layer 11 can be performed. This makes it possible to increase the final stress state of the semiconductive layer 13.

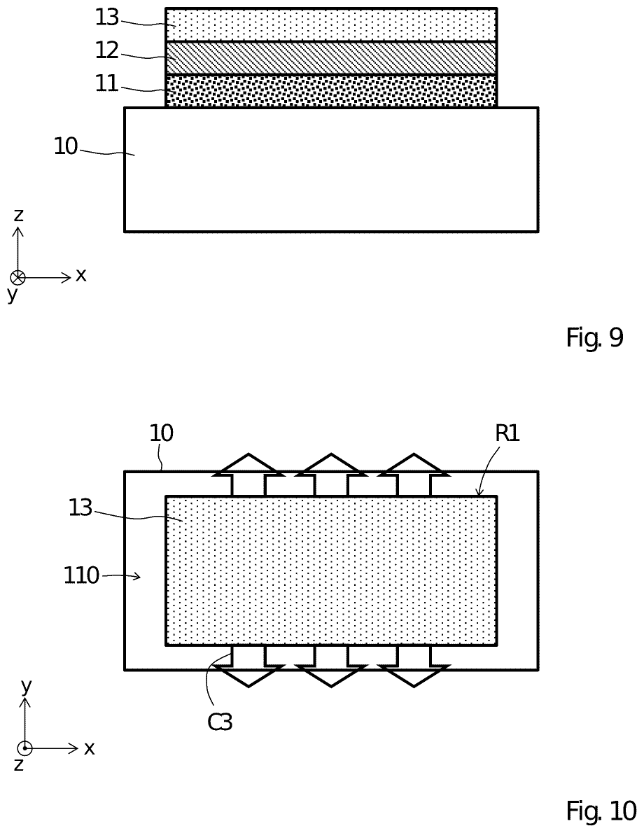

As illustrated in FIGS. 9, 10, after transfer, the stressor 14 can be removed. The semiconductive layer 13 thus preserves a uniaxial stress state C3. If the stressor 14 was in uniaxial tension, the semiconductive layer 13 is typically in uniaxial compression. If the stressor 14 was in uniaxial compression, the semiconductive layer 13 is typically in uniaxial tension, as illustrated in FIG. 10. In the case of a technology based on a mesa isolation, there is no filling of trenches 110 between regions R1, nor planarising step.

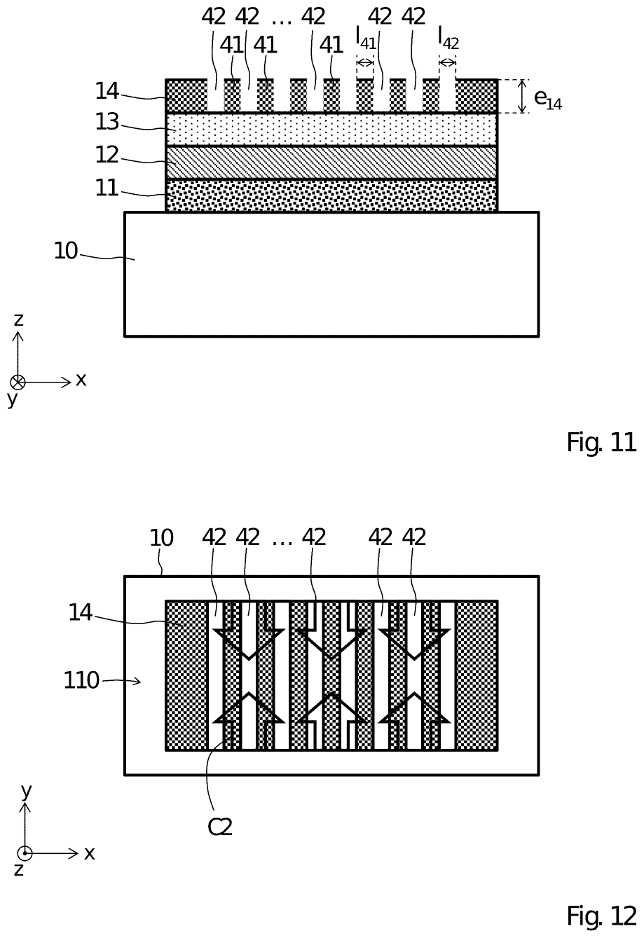

According to an option, after the stress transfer, a long annealing at a temperature less than the liquidus of the SiGe fuse layer 11 is performed. This makes it possible to diffuse the germanium in the support 10. The liquidus temperature of the fuse layer 11 is increased. This makes it possible to avoid the melting of the fuse layer 11, subsequently. FIGS. 11, 12 illustrate another embodiment of the step of altering the stressor 14. According to this embodiment, the alteration of the stressor 14 is obtained by forming relaxation trenches 42 in the thickness e₁₄ of the stressor 14, by etching. These relaxation trenches 42 preferably have a depth equal to the thickness e₁₄ of the stressor 14. They are mainly directly along y and regularly spaced apart from one another along x. This makes it possible to obtain stressor 14 strips 41, uniaxially stressed along y. The strips 41 have a width I₄₁ along x around equal to half the thickness e₁₄ of the stressor 14. The relaxation trenches 42 preferably have a width I₄₂ along x as small as enabled by lithography and etching. These relaxation trenches 42 make it possible to transform the biaxial stress state C1 of the stressor 14 into a uniaxial stress state C2. This embodiment is, in particular, directly applicable to all types and values of the non-zero biaxial stress state C1.

If the lithography enables the definition of trenches 42 in several directions of the plane xy, uniaxial stresses in different directions of the plane xy can be obtained. Moreover, outside of the regions R1 intended to be uniaxially stressed, the superposition of trenches 42 along x and along y advantageously makes it possible to obtain totally relaxed regions. Typically, such a trench pattern 42 is configured to form approximately square stressor 14 blocks, of side length of around half the thickness e₁₄ of the stressor. The method therefore advantageously makes it possible to produce different uniaxial stress states on certain regions, while enabling the joint production of relaxed stress states in other regions.

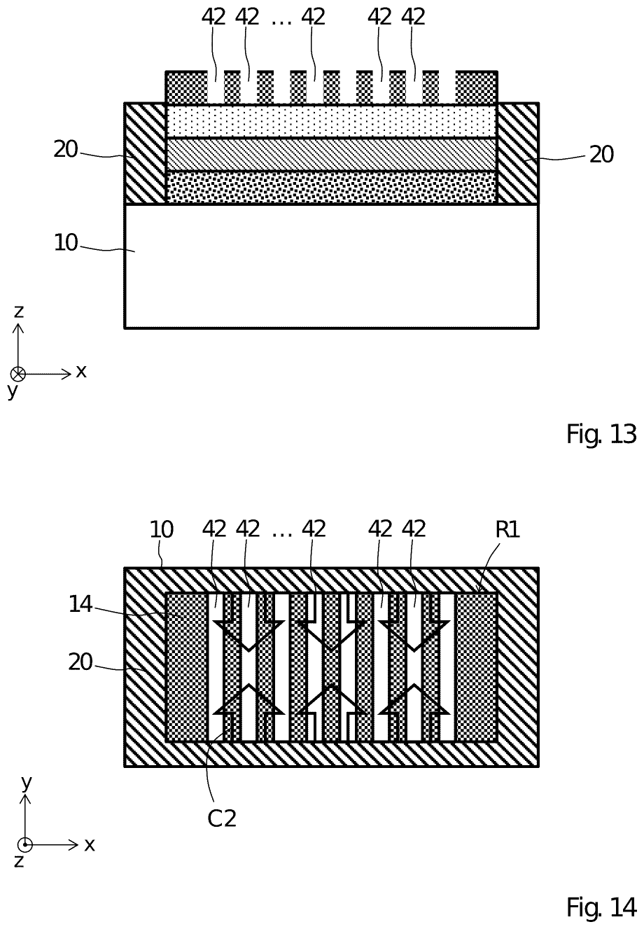

FIGS. 13, 14 illustrate another embodiment, wherein the trenches 110 are filled to form isolating trenches 20, after transfer of the stress state by temporary melting of the fuse layer 11, and before removal of the stressor 14. The regions R1 are thus confined laterally between the isolating trenches 20 before removal of the stressor 14. This makes it possible to avoid a relaxation by the free edges of the stack.

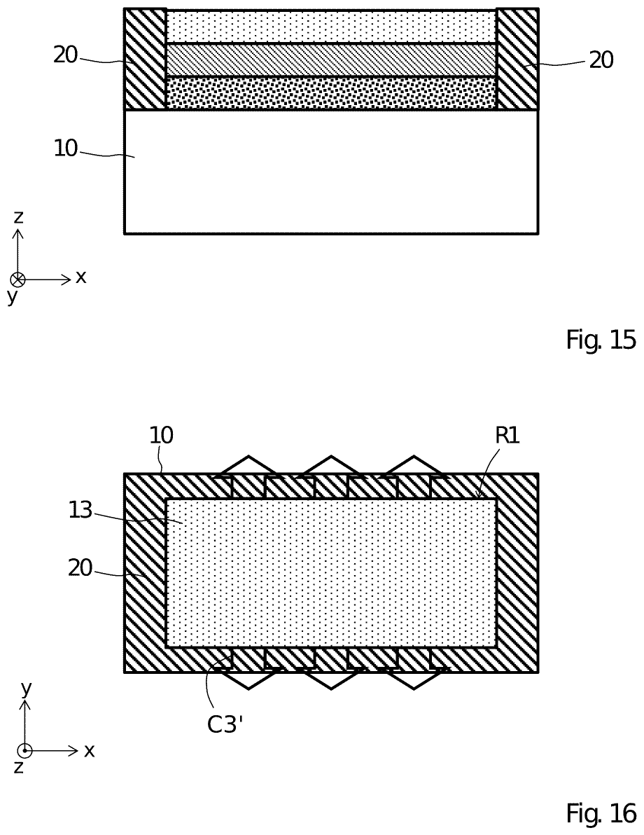

As illustrated in FIGS. 15, 16, after removal of the stressor 14, the uniaxial stress state C3′ in the semiconductive layer 13 is thus increased. According to an option, the isolating trenches 20 only extend along the planes yz, parallel to the direction of the uniaxial stress. This also favours the uniaxial stress increase in the semiconductive layer 13.

Through examples described above, it clearly appears that the method for producing a uniaxial stress state in a semiconductive layer according to the invention is particularly advantageous for applications of the field of microelectronics and/or optoelectronics. Producing transistors on such a uniaxially stressed semiconductive layer benefits, in particular, from a significant increase of the mobility of the charge carriers, in particular for MOSFET FDSOI, FinFET and MOSFET with stacked channels (“nanosheet”) architectures.

The invention is not limited to the embodiments described above. Different combinations of altering the stressor and of structuring the stack can be considered. These steps can be inverted or alternate.

1. A method for producing a uniaxial stress state in a semiconductive layer, the method comprising:
providing a stack comprising a support, the semiconductive layer, and a fuse layer inserted between the support and the semiconductive layer;
forming a stress donor layer on the semiconductive layer;
defining patterns after the forming of the stress donor layer;
forming, from the patterns, regions surrounded by trenches extending up to into the semiconductive layer;
partially altering the stress donor layer at the regions, configured to modify a first stress state of the stress donor layer, so as to obtain a second stress state mainly in a determined direction; and
at least partially melting the fuse layer, such that the stress donor layer transfers at least partially, by relaxation, the second stress state in the semiconductive layer, such that the semiconductive layer has a uniaxial stress state in the determined direction.

2. The method of claim 1, further comprising:
filling the trenches to form isolating trenches, after the at least partially melting of the fuse layer and before removing the stress donor layer.

3. The method of claim 1, wherein the partially altering comprises an ion implantation in a part of the stress donor layer forming implanted strips oriented in the determined direction, the implanted strips extending over the entire dimension of the stress donor layer in the determined direction.

4. The method of claim 3, wherein the first stress state is substantially zero and the second stress state corresponds to a uniaxial compression.

5. The method of claim 3, wherein the first stress state corresponds to a biaxial tension and the second stress state corresponds to a uniaxial tension.

6. The method of claim 1, wherein the partially altering comprises forming relaxation trenches in the stress donor layer, oriented in the determined direction.

7. The method of claim 6, wherein the relaxation trenches are separated by stress donor layer strips having a width around equal to half the thickness of the stress donor layer.

8. The method of claim 1, wherein the stack comprises an isolating layer between the semiconductive layer and the fuse layer.

9. The method of claim 1, wherein the stress donor layer is silicon nitride-based.

10. The method of claim 1, wherein the melting comprises rapid thermal annealing.

11. The method of claim 1, wherein the fuse layer is amorphous.

12. The method of claim 11, wherein the amorphous fuse layer is formed by epitaxy before being amorphized implantation.

13. The method of claim 1, wherein the semiconductive layer is silicon- or silicon-germanium-based and the fuse layer is silicon-germanium- or germanium-based and has a germanium content which is greater than the semiconductive layer.

14. A method for manufacturing a transistor, the method comprising:
implementing the method of claim 1, the transistor comprising a channel region made in the semiconductive layer.

15. The method of claim 1, wherein the semiconductive layer comprises silicon, and
wherein the fuse layer comprises silicon and germanium and has a germanium content which is greater than the semiconductive layer.

16. The method of claim 1, wherein the semiconductive layer comprises silicon and germanium, and
wherein the fuse layer comprises silicon and germanium and has a germanium content which is greater than the semiconductive layer.

17. The method of claim 1, wherein the semiconductive layer comprises silicon, and
wherein the fuse layer comprises silicon and germanium and has a germanium content which is greater than the semiconductive layer.

18. The method of claim 1, wherein the semiconductive layer comprises silicon and germanium, and
wherein the fuse layer comprises germanium and has a germanium content which is greater than the semiconductive layer.

19. The method of claim 1, wherein the melting comprises using a nanosecond laser.
